(19) United States
(12) Patent Application Publication
(10) Pub. No.: US 2014/0321037 A1
(43) Pub. Date: Oct. 30, 2014

(54) CABINET SERVER AND DUMMY SERVER CHASSIS

(71) Applicants: Hon Hai Precision Industry Co., Ltd., New Taipei (TW); Hong Fu Jin Precision Industry (Shenzhen) Co., Ltd, Shenzhen (CN)

(72) Inventor: CHAO ZHAO, Shenzhen (CN)

(73) Assignees: Hon Hai Precision Industry Co., Ltd., New Taipei (TW); Hong Fu Jin Precision Industry (Shenzhen) Co., Ltd, Shenzhen (CN)

(21) Appl. No.: 14/011,713

(22) Filed: Aug. 27, 2013

(30) Foreign Application Priority Data
Apr. 25, 2013 (CN) 2013101462592

(51) Int. Cl. H05K 7/14

(52) U.S. Cl. CPC H05K 7/1488
USPC 361/679.02; 312/223.2

(57) ABSTRACT

A dummy server chassis to block an idle opening in a cabinet server includes a first blocking member and a second blocking member. The first blocking member covers the idle opening, and the second blocking member covers a lower server unit adjacent to the idle opening. The second blocking member includes a bracket extending from a side of the first blocking member, and a covering plate mounted to the bracket.

### BACKGROUND

1. Technical Field

The present disclosure relates to a cabinet server with a dummy server chassis.

2. Description of Related Art

A cabinet server usually includes a plurality of server units received in the cabinet. When one server unit is taken out for maintenance, an opening will be left in the cabinet, which makes heat dissipation of the server units inefficient.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric view of an embodiment of a cabinet server with an opening.

FIG. 2 is an isometric view of the cabinet server of FIG. 1, with a dummy server chassis received in the opening.

FIG. 3 is an enlarged view of the dummy server chassis of FIG. 2.

FIG. 4 is an exploded, isometric view of the dummy server chassis of FIG. 3.

FIG. 5 is an enlarged view of the circled portion V of FIG. 4.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean “at least one.”

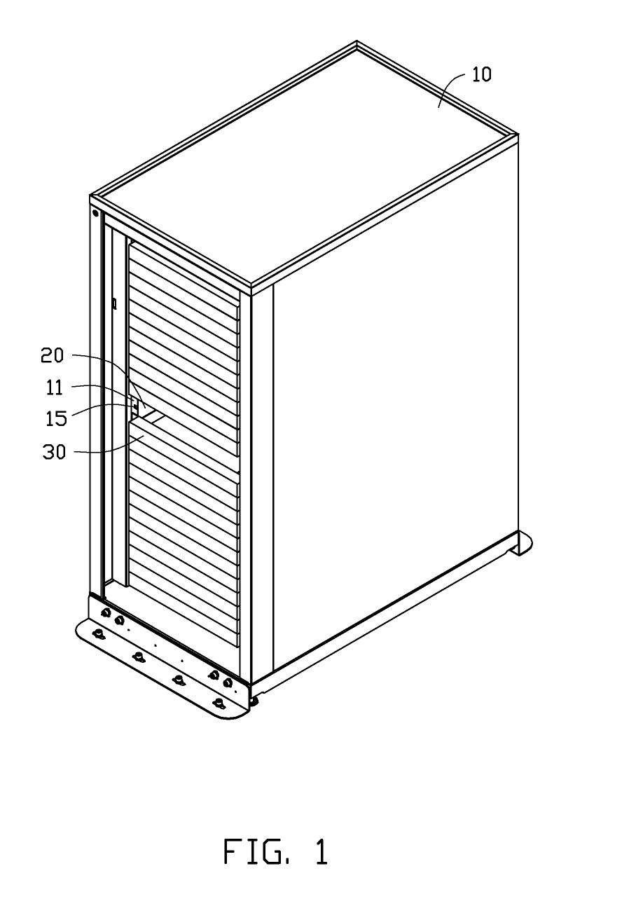

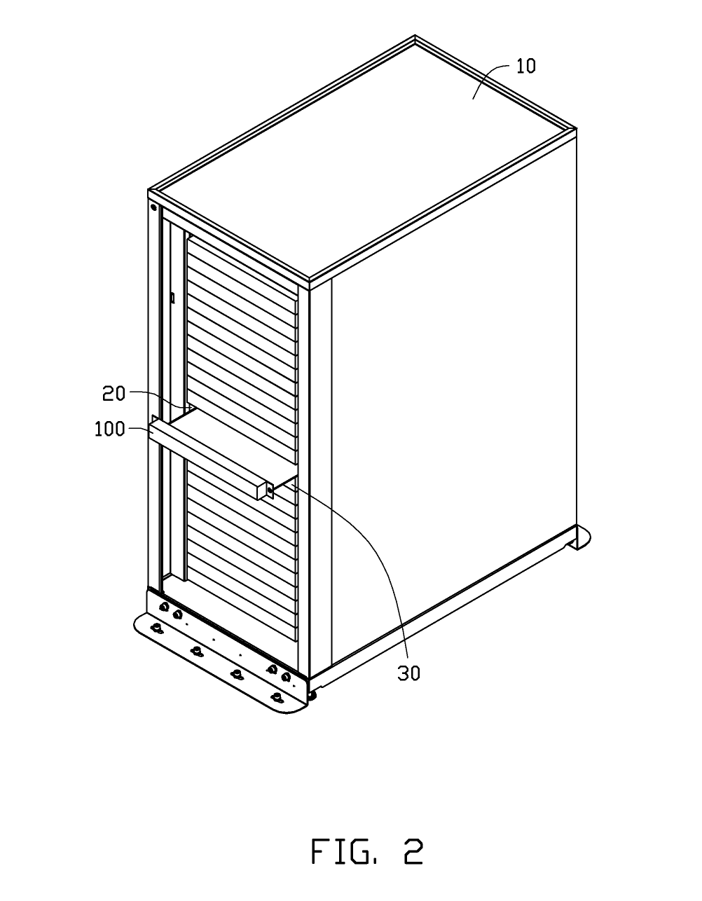

Referring to FIGS. 1 and 2, an embodiment of a cabinet server 10 includes a cabinet 11, a plurality of server units 30 without an upper cover, and a dummy server chassis 100.

The cabinet 11 defines a plurality of openings 20 for receiving the server units 30 and the dummy server chassis 100. The cabinet 11 defines two mounting holes 15 beside each opening 20.

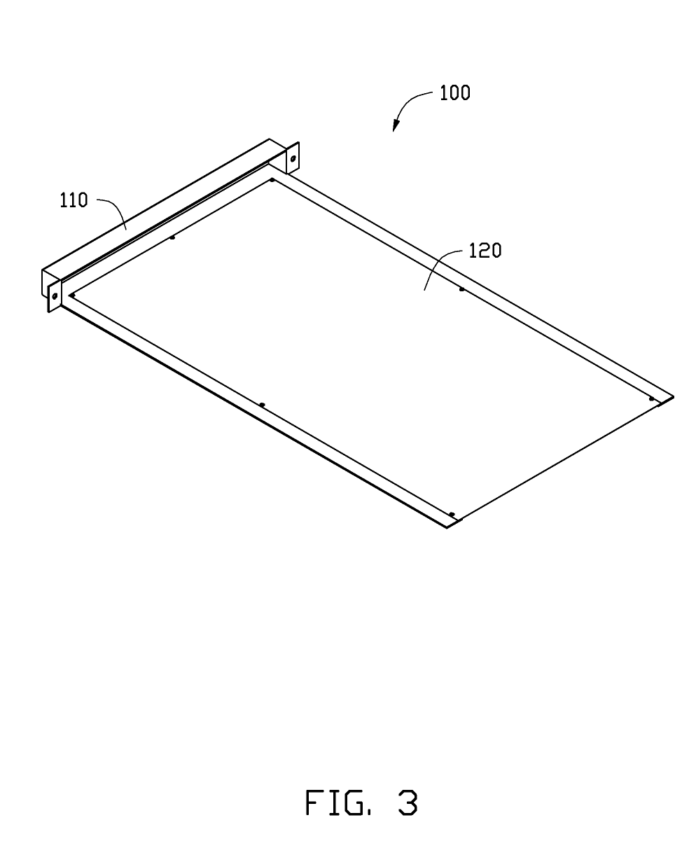

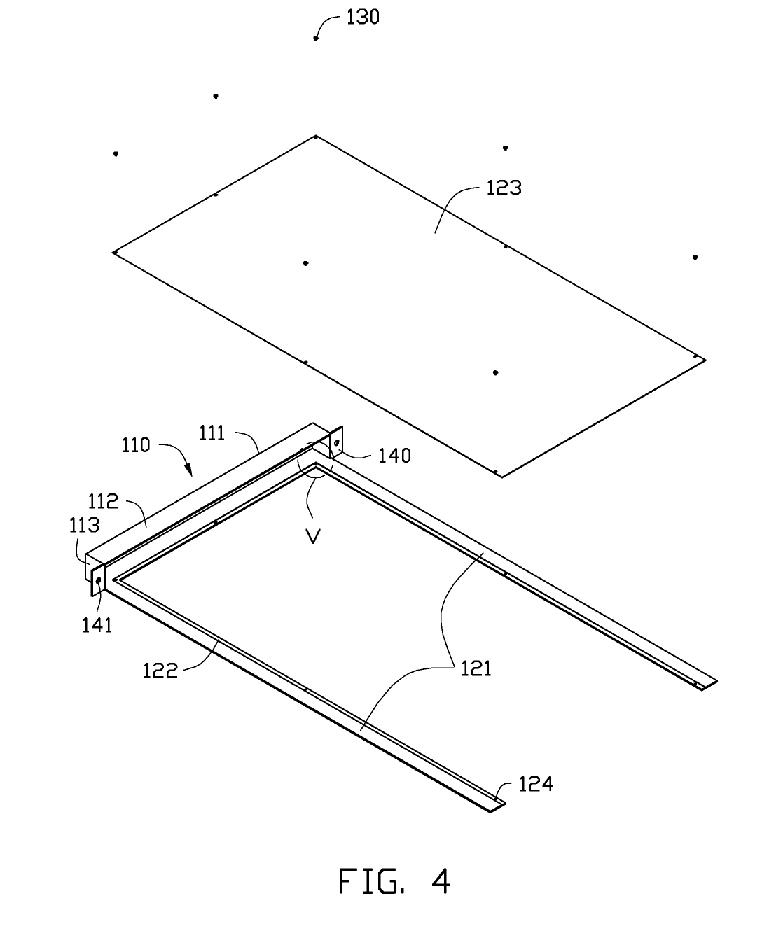

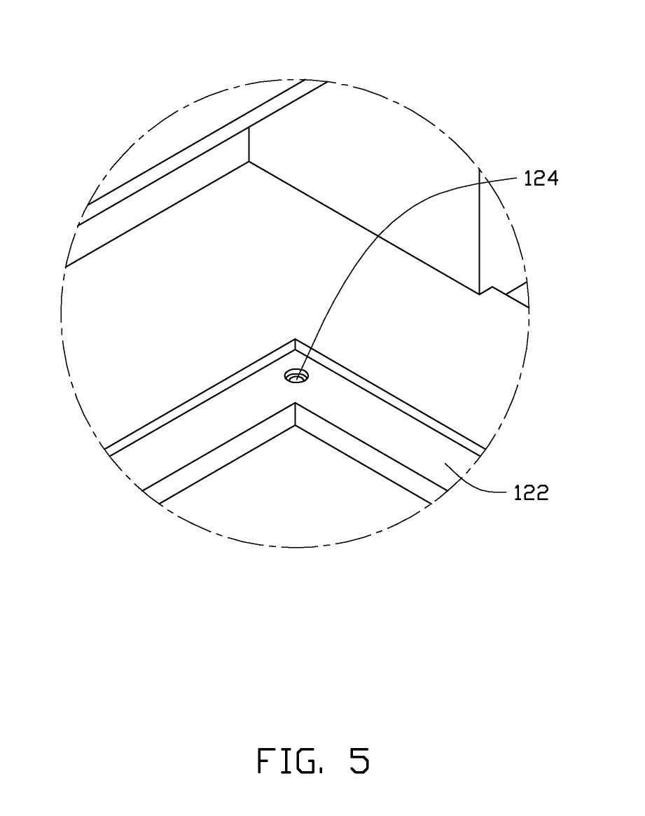

Referring to FIG. 3 to FIG. 5, the dummy server chassis 100 includes a first blocking member 110, a second blocking member 120, and a plurality of screws 130. The first blocking member 110 includes a blocking plate 111, a top plate 112 extending from a top of the blocking plate 111, and two side plates 113 extending from opposite sides of the blocking plate 111. A mounting piece 140 extends out from each side plate 113, and each mounting piece 140 defines a through hole 141.

The second blocking member 120 includes a U-shaped bracket 121 extending from a side of the blocking plate 111, and a covering plate 123. A U-shaped depressed assembling portion 122 is defined in an inner side of the bracket 121. A plurality of screw holes 124 is defined in the assembling portion 122. The screws 130 extend through the covering plate 123 to screw into the screw holes 124, to fix the covering plate 123 to the bracket 121.

In use, the dummy server chassis 100 is inserted into an idle opening 20.

The bracket 121 and the covering plate 123 are located above an adjacent lower server unit 30, to cover a top of the adjacent lower server unit 30. Two screws extend through the through holes 141 to screw into the mounting holes 15, to mount the dummy server chassis 100 to the cabinet 11. The first blocking member 110 covers the idle opening 20. In the embodiment, the first blocking member 110 and the bracket 121 are made of electromagnetic radiation shielding material, such as steel, for shielding the idle opening 20.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A dummy server chassis, comprising:
a first blocking member comprising a blocking plate, a top plate extending from a top side of the blocking plate, and two side plates extending from opposite ends of the blocking plate; and
a second blocking member comprising a bracket extending from a bottom side of the blocking plate, and a covering plate mounted to the bracket.

2. The dummy server chassis of claim 1, wherein a mounting piece extends out from each of the side plates and defines a through hole.

3. The dummy server chassis of claim 1, wherein the bracket is U-shaped, a U-shaped depressed assembling portion is defined in an inner side of the bracket, a plurality of screw holes is defined in the assembling portion, a plurality of screws extends through the covering plate to screw into the plurality of screw holes, to fix the covering plate to the bracket.

4. A cabinet server comprising:
a plurality of server units;
a dummy server chassis; and
a cabinet defining a plurality of openings for receiving the plurality of server units and the dummy server chassis;
wherein the dummy server chassis comprises a first blocking member for covering one of the openings receiving the dummy server chassis, and a second blocking member for covering a top of an adjacent one of the server units below the dummy server chassis.

5. The cabinet server of claim 4, wherein the second blocking member comprises a bracket extending from a side of the first blocking member, and a covering plate mounted to the bracket.

6. The cabinet server of claim 5, wherein the first blocking member comprises a blocking plate, a top plate extending from a top of the blocking plate, and two side plates extending from opposite ends of the blocking plate.

7. The cabinet server of claim 6, wherein a mounting piece extends out from each of the side plates and defines a through hole, the cabinet defines two mounting holes beside each opening, two screws extend through the through holes of the side plates to screw in the mounting holes.

8. The cabinet server of claim 6, wherein the bracket is U-shaped and extends from a bottom of the blocking plate, a U-shaped depressed assembling portion is defined in an inner side of the bracket, a plurality of screw holes is defined in the assembling portion, a plurality of screws extends through the covering plate to screw into the plurality of screw holes, to fix the covering plate to the bracket.
